(19) United States
(12) Patent Application Publication
(10) Pub. No.: US 2026/0052824 A1
(43) Pub. Date: Feb. 19, 2026

(54) BLACK MATRIX INTEGRATION

(71) Applicant: VueReal Inc., Waterloo (CA)

(72) Inventor: Gholamreza CHAJI, Kitchener (CA)

(73) Assignee: VueReal Inc., Waterloo, ON (CA)

(21) Appl. No.: 19/120,472

(22) PCT Filed: Oct. 13, 2023
(86) PCT No.: PCT/CA2023/051358

§ 371 Date: Apr. 11, 2025

Related U.S. Application Data
(60) Provisional application No. 63/415,692, filed on Oct. 13, 2022.

(51) Int. Cl. H10H 29/855; H01L 25/16; H10F 39/00; H10H 29/49; H10H 29/856

(52) U.S. Cl. CPC H10H 29/8552; H01L 25/167; H10F 39/8057; H10F 39/8067; H10H 29/49; H10H 29/856

(57) ABSTRACT

The present invention discloses methods to reduce a surface reflection and improve a contrast in an optoelectronic system with microdevices that may comprise of microLED's, microsensors, MEMS, or another type of semiconductor or optoelectronic device. In particular, there is use of black matrix, pixel circuit layers, reflective layers, optical structures, photo definable polymer and dielectrics. Here the optical structure may comprise wavelength tuning materials.

### BACKGROUND AND FIELD OF THE INVENTION

The invention is related to an optoelectronic system comprising pixels.

### SUMMARY

The present invention relates to a method to reduce a surface reflection and improve a contrast in an optoelectronic system, the method comprising, having a backplane substrate, forming a layer of pixel circuit on a surface of the backplane substrate and forming a layer of a black matrix on the backplane substrate and integrating microdevices to the backplane substrate.

### BRIEF DESCRIPTION OF DRAWINGS

The foregoing and other advantages of the disclosure will become apparent upon reading the following detailed description and upon reference to the drawings.

FIG. 1A shows a backplane substrate where a layer of the pixel circuit is formed on its surface.

FIG. 1B, shows another optical structure 130 can be added to the microdevice.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The invention is related to an optoelectronic system comprising pixels, with each pixel having at least one microdevice integrated. The microdevice can be a microLED, microsensor, MEMS, or another type of semiconductor or optoelectronic device.

The invention outlines a method to improve the optoelectronic system and also outlines a structure for the optoelectronic system.

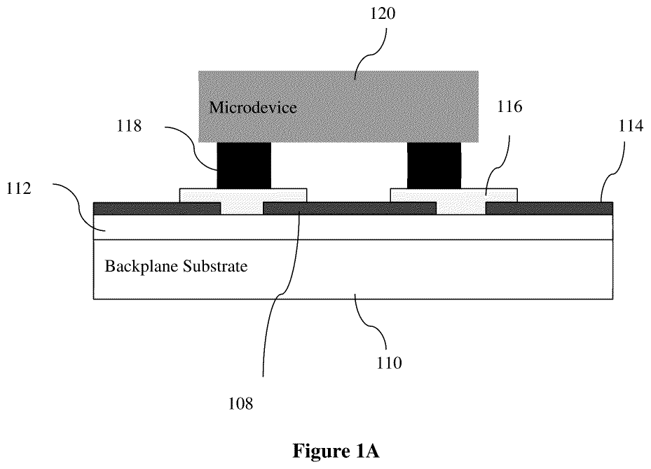

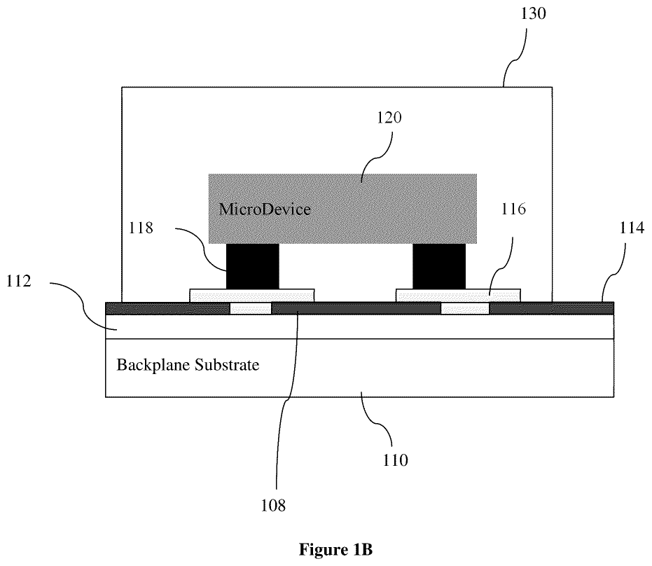

As shown in FIG. 1A, the system can have a backplane substrate 110 where a layer of the pixel circuit (TFT layers) 112 is formed on its surface. The pixel circuit layers can be metals, dielectric, or semiconductor materials. The pixel circuit layers or the backplane substrate 110 can be reflective and therefore affect the system performance such as contrast under the ambient conditions. In order to reduce the surface reflection and improve the contrast in the optoelectronic system 100, a layer of the black matrix 114 is formed on backplane substrate 110.

The black matrix 114 can have an opening for backplane pads 116. The backplane pads can be formed before the black matrix 114 or after the black matrix formation. The pads can cover part of the black matrix 114. The microdevice 120 is coupled to the pixel layers (TFT layers) 112 through the backplane pads 116 and microdevice pads 118. The microdevice is integrated into the substrate after forming the black matrix 114. Therefore, the black matrix does not cover the side wall or surface of the microdevice 120. In one related embodiment, other layers such as adhesive can be added to assist the microdevice integration. The adhesive layer can be on top of the black matrix. In another related embodiment, the black matrix is removed from the area of the adhesive to provide stronger adhesion to the backplane or pixel layers.

In one related embodiment the layer 108 under the microdevice 120 can be reflective to reflect the light. The layer can be added on top of the black matrix or black matrix can be removed from the top of the reflective layer in this area.

In another related embodiment, as shown in FIG. 1B, another optical structure 130 can be added to the microdevice. The layer 130 can be one or more of the wavelength tuning material such as color conversion (e.g., Qdot, phosphor or other material), wavelength filtration material such as color filter, bank structure, protective layer such as passivation, or wave forming/shaping structure such as lens. In one related embodiment, the structure 130 can be a film covering more than one pixel area. In another related embodiment, to reduce the reflection from the structure 130, the optical structure 130 can be patterned to cover the microdevice or extend from the edge of the microdevice.

The black matrix 114 can be a photo definable polymer that can be patterned. In another related embodiment, the black matrix 114 can be a stack of dielectric to block a specific range of wavelengths.

In another related embodiment, the microdevice is integrated into the backplane or pixel layers and the black matrix is added after. Here, the black matrix is patterned to not cover the surface of the microdevices. The microdevices can have reflective structure on the side to prevent the lights from the side going to the black matrix. In another related embodiment, a reflective layer covers the edge of black matrix around the microdevices.

While the present disclosure is susceptible to various modifications and alternative forms, specific embodiments or implementations have been shown by way of example in the drawings and will be described in detail herein. However, it should be understood that the disclosure is not intended to be limited to the particular forms disclosed. Rather, the disclosure is to cover all modifications, equivalents, and alternatives falling within the spirit and scope of the invention as defined by the appended claims.

1. A method to reduce a surface reflection and improve a contrast in an optoelectronic system, the method comprising:
having a backplane substrate;
forming a layer of pixel circuit on a surface of the backplane substrate;
forming a layer of a black matrix on the backplane substrate; and
integrating microdevices to the backplane substrate.

2. The method of claim 1, wherein the pixel circuit or the backplane substrate are reflective.

3. The method of claim 1, wherein pixel circuit layers comprise one of metals, dielectrics or semiconductors.

4. The method of claim 1, wherein the black matrix has an opening for backplane pads.

5. The method of claim 4, wherein the backplane pads are formed before the black matrix or after the black matrix formation.

6. The method of claim 4, wherein a microdevice is coupled to the pixel circuit layer through the backplane pads and microdevice pads.

7. The method of claim 1, wherein an adhesive layer is on a top of the black matrix.

8. The method of claim 7, wherein the black matrix is removed from the area of the adhesive.

9. The method of claim 1, wherein a layer under the microdevice is reflective.

10. The method of claim 9, wherein the layer is added on top of the black matrix, or the black matrix is removed from a top of the reflective layer.

11. The method of claim 1, wherein another optical structure is added to the microdevice wherein the optical structure is one or more of a wavelength tuning material such as a color conversion, a wavelength filtration material such as a color filter or a bank structure, a protective layer such as passivation, or a wave forming/shaping structure such as a lens.

12. The method of claim 11, wherein the optical structure is a film covering more than one pixel area.

13. The method of claim 11, wherein the optical structure is patterned to cover the microdevice or to extend from an edge of the microdevice.

14. The method of claim 1, where the black matrix is a patternable photo definable polymer.

15. The method of claim 1, where the black matrix is a stack of dielectric to block a specific range of wavelengths.

16. The method of claim 1, wherein the microdevice is integrated into the backplane substrate or the pixel layers and the black matrix is added after.

17. The method of claim 16, wherein the black matrix is patterned to not cover the surface of the microdevices.

18. The method of claim 17, wherein the microdevices have a reflective structure on a side to prevent the lights from the side going to the black matrix.

19. The method of claim 18, wherein a reflective layer covers an edge of the black matrix around the microdevices.
